(19) United States
(12) Patent Application Publication
(10) Pub. No.: US 2004/0130396 A1
(43) Pub. Date: Jul. 8, 2004

(54) VHF/UHF broadband high power amplifier module

(76) Inventor: Sou-Bin Chen, Taipei (TW)

Correspondence Address: JOHNSON & ASSOCIATES PC, 14625 BALTIMORE AVENUE #282, LAUREL, MD, 20707, US

(21) Appl. No.: 10/335,268

(22) Filed: Jan. 2, 2003

(51) Int. Cl. H03F 3/191

(52) U.S. Cl. 330/302

(57) ABSTRACT

A VHF/UHF broadband high power amplifier module of the present invention comprising: a broad/narrow band attenuator for attenuating input signal source; a broadband matcher coupled to said broad/narrow band attenuator for impedance matching said attenuated input signal source; a micro-strip line circuit coupled to said broad band matcher to perform first impedance transformation; a power transistor coupled to said micro-strip line circuit to perform AB class push pull amplification; a broad band matcher coupled to said power transistor and a load to perform second impedance transformation of said load; and said transformed low impedance to become the load of said Rf power transistor.

### BACKGROUD OF INVENTION

1. Field of the Invention

The present invention relates to a VHF/UHF broadband high power amplifier module. More specifically, the present invention relates to a VHF/UHF broadband high power push-pull amplifier module design with 100 MHz-500 MHz 100 W output power module, and with a whole bandwidth having 100 W output power and a 12 dB gain at 500 MHz.

2. Description of Related Art

Now a days radio communication technology has become more popular and widely used in various fields. However, for radio communication to get across to remote site power amplifiers are needed to send information to respective receivers. Various power amplifiers are used in commercial and military applications. This is especially true in the electronic communication warfare business. Electronic communication warfare has very important role to play in modern military operations, and the communication jamming electronics of electronic communication warfare require power amplifiers to successfully conduct counter electronics warfare.

Modem military communications often use hopping frequency technology in communication electronics. The use of hopping frequency technology requires broadband rapid response power amplifier for successful jamming of communication electronics. Because broadband high power amplifier module is a key component of a broadband rapid response power amplifier, a broadband high power amplifier module is an important and intricate part of communication jamming electronics.

In general, RF amplifiers are categorized as small signal output power amplifiers and as large signal output power amplifiers,. Small signal output power amplifiers normally use Y or S parameter equation for circuit design. As for large signal output power amplifiers, the manufacturer of RF power transistor may not provide S parameter in their product's manual. Although some manufacturers would provide some products with S parameter, these products may well not fulfill the design requirements, and therefore these large signal output power amplifier may well not be able to use Y or S parameter for circuit design.

Most manufacturers of RF power transistor may provide, under certain conditions, input impedance (Zᵢₙ) and output impedance (Z_{OL}) with fixed output power levels for large signal high power transistor Thus user may use Zᵢₙ, signal source Z_{OL} and load to match their impedance and obtain required output power. Therefore, there is a need to consider the frequency operation range and the amount of output power required during the technical applications of RF power amplifier circuit.

There are two kinds of operation frequency range design: one broad band and one narrow band circuit design. If manufacturers were to supply S parameter power transistor, one would probably have to refer to S parameter at the highest, the middle and the lowest three operational frequency points of the bandwidth for the appropriate circuit design, and then referred to a SMITH CHART for designing the input and the output circuits. However these circuits may only be able to reach 1 to 2 times as large as its operational bandwidth. When these circuits reach bandwidth of 2 times or greater, one has to adopt broadband impedance transformer for impedance match circuit design. This is especially true when designing VHF and UHF circuits with bandwidths two times or greater because manufacturers can only provide input impedance Zᵢₙ and output impedance Z_{OL} with fixed output power levels. Thus for impedance circuit design of such broadband power amplifier, one has no choice but to adopt broadband impedance transformer for impedance match circuit design. The design steps, though not limited, are described as follows:

1. determine load R_{L} from Output Power Pₒ,

R_{L}=K(V_{CC}−V_{SA})2/2 [symbol] P_{O}

where

V_{cc}: operation voltage

Vₛₐ: saturation voltage

2. determine impedance ratio of output broadband impedance transformer

N_{L}=50/2 [symbol] R_{L}

3. determine coaxial cable characteristic impedance Z_{OL} of output broadband impedance transformer

Z_{OL}=\sqrt{2R_{L}×50}

4. boost input impedance from Zᵢₙ to Zᵢₙ′.

5. determine impedance ratio N_{I} of input broadband impedance transformer

N_{I}=50/2 [symbol] Zᵢₙ′

6. determine coaxial cable characteristic impedance Z_{OI} of input broadband impedance transformer

Z_{OI}=\sqrt{2Z_{IN}″×50}

7. circuit design completed

For 100 MHz˜500 MHz 100 W output power module, the prior art design adopts broadband impedance transformer for impedance match with output power of 80 W to 100 W, with gain at 500 W of about 6˜10 dB, and gain flatness within the whole bandwidth of about [symbol] 3 dB, and efficiency less than 40%.

### SUMMARY OF THE INVENTION

From the aforementioned descriptions, it is obvious that the output power module of the prior art is unable to output 100 W all over the bandwidth of 100 MHz˜500 MHz, the gain at 500 MHz is less than 10 dB, and the variation of gain in between high and low band is relative large, and efficiency is low.

Thus, an object of the broadband high power module of the present invention is to use a VHF/UHF broadband high power module for developing a push-pull designed 100 MHz˜500 MHz 100 W output power module as over the whole bandwidth.

Another object of this invention is to provide a broadband high power module with 100 W output, gain of 12 dB at 500 MHz with variation of gain in between high and low band within [symbol] 1.5 dB, and wherein the efficiency may reach 45% and above.

Still, another object of this invention is to provide a broad-band high power module at a reduced cost and capable of efficient heat dissipation irrespective of the bulky broadband high power system structure.

Still further, another object of the present invention is to provide an electronic circuit configured to provide said broadband high power performance for broadband high power amplifier module, which may be used in both commercial and military applications.

The present invention will be readily apparent upon reading the following description of a preferred exemplified embodiment of the invention and upon reference to the accompanying drawings.

### BRIEF DESCRIPTION OF DRAWINGS

FIG. 1 is a block diagram of VHF/UHF broadband high power amplifier module of the present invention.

FIG. 2 is a S₁₁ static test block diagram of 100 MHz˜500 MHz 100 W broadband high power amplifier module of the preferred embodiment of the present invention.

FIG. 3 is a S₂₁ static test block diagram of 100 MHz˜500 MHz 100 W broadband high power amplifier module of the preferred embodiment of the present invention.

FIG. 4 is a dynamic test block diagram of 100 MHz˜500 MHz 100 W broadband high power amplifier module of the preferred embodiment of the present invention.

FIG. 5-1 is a component side of PCB layout of the preferred embodiment of the present invention.

FIG. 5-2 is a copper track side of PCB layout of the preferred embodiment of the present invention.

### DETAILED DESCRIPTION AND PREFERRED EMBODIMENTS

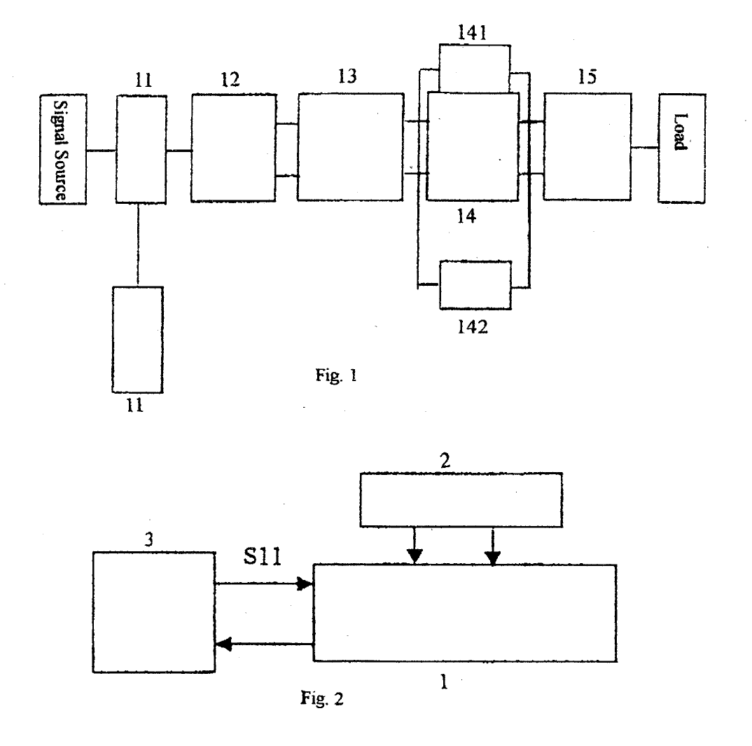

FIG. 1 shows a block diagram of the VHF/UHF broadband high power amplifier module of the present invention consisting of a broad/narrow band frequency attenuator 11, a micro strip line circuit 13, a push-pull power transistor 14 and a broadband matcher 15, wherein said broad/narrow band frequency attenuator 11 is used to attenuate input signal source for improving stability of the VSWR and the gain flatness. It is preferred to use T type R, L, C serial circuit, as the attenuation quantity is inversely proportional to the operational frequency.

Still referring to FIG. 1, the broadband matcher 12 is coupled to the broad/narrow band frequency attenuator 11 to perform impedance matching for the attenuated signal source he micro strip line circuit 13 is coupled to the broadband matcher 12 to perform impedance transformation by boosting 3 Ω input impedance to 12.5 Ω in three stages and then subsequently raising the input impedance to 50 Ω through a broadband impedance transformer. The RF power transistor 14 is coupled to the micro strip line circuit 13 to perform AD class push-pull amplification, and the broadband matcher 15 is coupled to the RF power transistor 14 and a load 16 to perform 9:1 impedance transformation. The transformed low impedance is a load of the push-pull transistor 14 and negative feedback circuits 141 and 142 are added on the input and output terminals of the RF power transistor 14 circuit to improve its stability and the gain flatness.

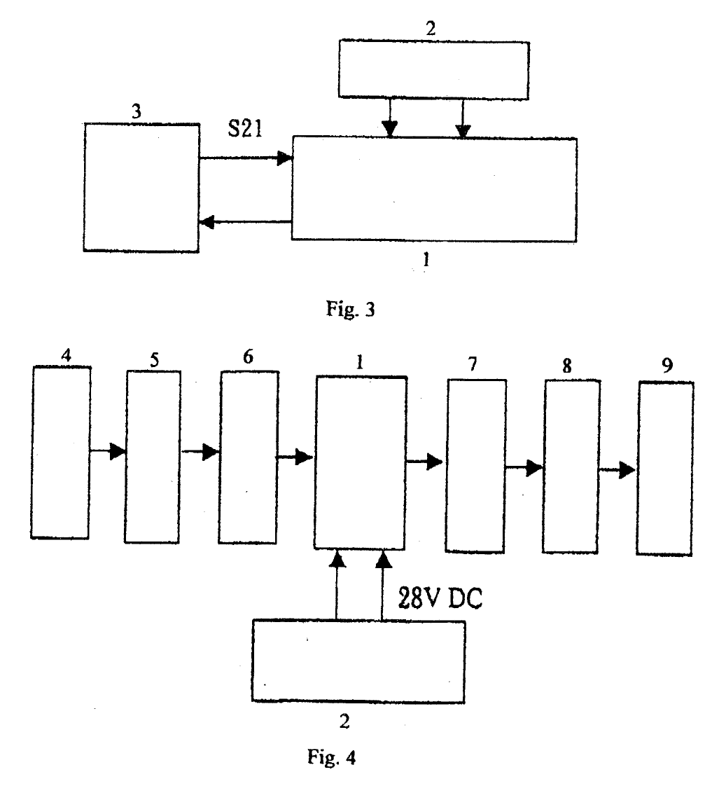

FIGS. 2 and 3 show static test block diagrams of the present invention. First, FIG. 2 shows a S₁₁ static test block diagram of 100 MHz˜500 MHz 100 W broadband high power amplifier module of the preferred embodiment of the present invention. Consistent with FIG. 2, S₁₁ static test (electrical characteristic measurement with I_{DQ} in operation) is performed at an operational current of 1.6 A and the network analyzer 3 directly measures the return loss of S₁₁ over the whole bandwidth of the broadband high power amplifier module as ≦−10 dB.

Similarly, FIG. 3 shows a S₂₁ static test block diagram of 100 MHz˜500 MHz 100 W broadband high power amplifier module of the preferred embodiment of the present invention. Consistent FIG. 2, S₂₁ static test is performed at an operational current of 1.6 A and the network analyzer 3 direct measures the return loss of S₂₁ over the whole bandwidth of broadband high power amplifier module as ≧12 dB.

Referring to FIG. 4, is shown a dynamic test block diagram of 100 MHz˜500 MHz 100 W broadband high power amplifier module of the preferred embodiment of the present invention, wherein the static operational current of the broadband high power amplifier module 1 is 1.6 A. The output RF signal of the RF signal generator 4 is amplified by a class A push-pull amplifier 5 and the amplified RF signal output from class A push-pull amplifier 5 is sufficient to drive the tested broadband power module 1 to output 100 W and above.

The input power meter 6 and output power meter 7 are capable of measuring forward and backward power respectively, and the amplified 100 W RF signal of the broadband power module 1 is fed to a 50 dB attenuator 8 for attenuation, and then the attenuated RF signal is coupled to the spectrum analyzer 9 to measure each order of the harmonics. The data measured over the whole bandwidth of 100 MHz˜500 MHz 100 W power amplifier is as follows:

| Frequency | | | | G_{A} | 2_{nd} | 3_{rd} | | |
|---|---|---|---|---|---|---|---|---|
| (MHz) | P₁(W) | P₀(W) | I_{A}(A) | (−dB) | (−dB) | (−dB) | S₁₁ | Remark |
| 100 | 7.3 | 100 | 8.8 | 11.3 | 18 | 14 | 1.8 | |
| 110 | 7 | 100 | 8.6 | 11.5 | 20 | 16 | 1.8 | |
| 120 | 6.6 | 100 | 8.5 | 11.8 | 20 | 18 | 1.9 | |
| 130 | 6.3 | 100 | 8.0 | 12 | 21 | 19 | 1.9 | |
| 140 | 6.4 | 100 | 7.5 | 11.9 | 23 | 19 | 1.9 | |
| 150 | 5.5 | 100 | 6.7 | 12.5 | 20 | 17 | 1.8 | |
| 160 | 5.2 | 100 | 6.2 | 12.8 | 20 | 18 | 1.6 | |
| 170 | 4.7 | 100 | 6.0 | 12.2 | 20 | 16 | 1.6 | |
| 180 | 4.4 | 100 | 6.2 | 13.5 | 20 | 15 | 1.6 | |
| 190 | 4.6 | 100 | 6.3 | 13.3 | 23 | 18 | 1.7 | |
| 200 | 4.7 | 100 | 6.3 | 13.2 | 24 | 20 | 1.7 | |
| 220 | 4.8 | 100 | 6.1 | 13.1 | 24 | 27 | 2.0 | |
| 240 | 5.0 | 100 | 6.7 | 13 | 27 | 38 | 1.9 | |
| 260 | 4.9 | 100 | 7.0 | 13.1 | 26 | 38 | 1.9 | |
| 280 | 4.9 | 100 | 7.0 | 13.1 | 28 | 30 | 1.9 | |
| 300 | 5.4 | 100 | 7.5 | 12.6 | 32 | 36 | 1.6 | |
| 320 | 5.4 | 100 | 8.0 | 12.6 | 42 | 52 | 1.5 | |
| 340 | 5.2 | 100 | 7.4 | 12.8 | 52 | 49 | 1.5 | |
| 360 | 5.5 | 100 | 7.5 | 12.5 | 48 | 56 | 1.5 | |
| 380 | 6.1 | 100 | 8.0 | 12.1 | 40 | 67 | 1.3 | |
| 400 | 6.4 | 100 | 7.8 | 11.9 | 38 | 58 | 1.3 | |
| 420 | 6.3 | 100 | 7.5 | 12 | 34 | 54 | 1.7 | |
| 440 | 6.1 | 100 | 7.2 | 12.1 | 40 | 54 | 1.7 | |
| 460 | 7.2 | 100 | 7.0 | 11.4 | 48 | 51 | 1.3 | |
| 480 | 6.9 | 100 | 7.2 | 11.6 | 58 | 50 | 1.2 | |
| 500 | 7.0 | 100 | 7.0 | 11.5 | 62 | 48 | 1.4 | |

From the aforementioned descriptions, the high power module 1 of the present invention is capable of outputting 100 W power over the whole bandwidth 100 MHz˜500 MHz with impedance transformer to perform impedance matching crossing the input and output terminal respectively. The impedance transformer uses a coaxial cable with fixed length such that the production is easy reproducible and no adjustment is required thereby reducing the cost of production.

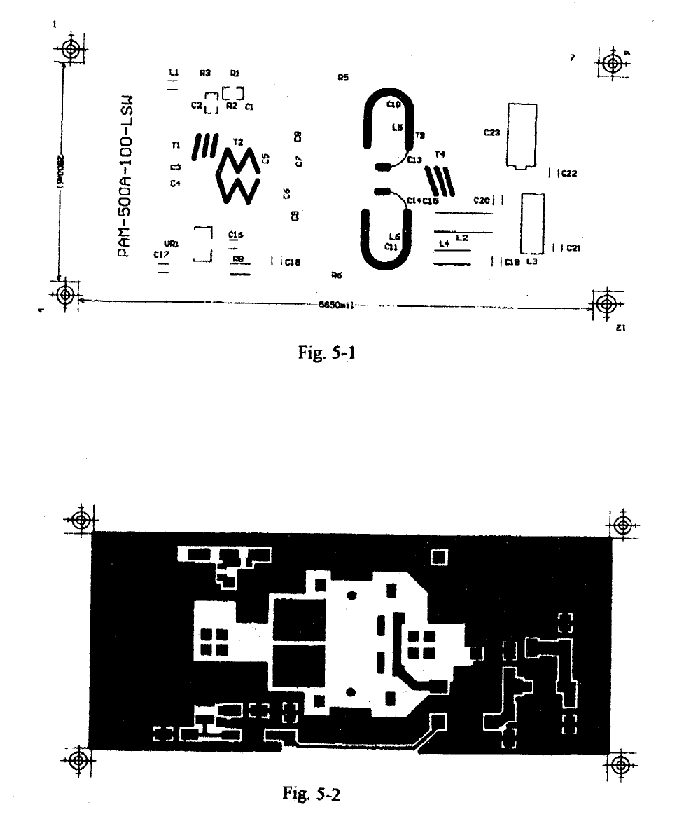

Finally, FIG. 5-1 shows a component side of the PCB layout of the preferred embodiment of the present invention, and FIG. 5-2 shows a copper track side of the PCB layout of the preferred embodiment of the present invention incorporated here for reference.

Various additional modification of the embodiments specifically illustrated and described herein will be apparent to those skilled in the art in light of the teachings of this invention. The invention should not be construed as limited to the specific form and examples as shown and described. The invention is set forth in the following claims.

What is claimed is:

1. A VHF/UHF broadband high power amplifier module of the present invention comprising:
a broad/narrow band attenuator for attenuating input signal source;
a broad band matcher coupled to said broad/narrow band attenuator for impedance matching said attenuated input signal source;
a micro-strip line circuit coupled to said broad band matcher to perform first impedance transformation;
a Rf power transistor coupled to said micro-strip line circuit to perform AB class push pull amplification; and
a broad band matcher coupled to said Rf power transistor and
a load to perform second impedance transformation of said load, and said transformed low impedance is the load of said Rf power transistor.

2. The VHF/UHF broadband high power amplifier module as in claim 1, wherein broad/narrow band frequency attenuator uses T type R, L, C serial circuit and attenuation quantity is inversely proportion to operational frequency.

3. The VHF/UHF broadband high power amplifier module as in claim 1, wherein said micro-strip line circuit is coupled to said broadband matcher to perform impedance transformation by boosting 3 Ω input impedance to 12.5 Ω in three stages, and then subsequently raising said input impedance to 50 Ω through a broadband impedance transformer.

4. The VHF/UHF broadband high power amplifier module as in claim 1, wherein said second impedance transformation of said broadband matcher is a 9:1 impedance transformation.

5. The VHF/UHF broadband high power amplifier module as in claim 1, wherein said Rf power transistor circuit further includes negative feedback circuits added on its input and output terminals respectively to improve stability and the gain flatness.
